(19) United States
(12) Patent Application Publication
(10) Pub. No.: US 2009/0321766 A1
(43) Pub. Date: Dec. 31, 2009

(54) LED

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/422,297

(22) Filed: Apr. 13, 2009

(30) Foreign Application Priority Data
Jun. 27, 2008 (CN) 200810068067.3

(51) Int. Cl. H01L 33/00

(52) U.S. Cl. 257/98; 257/99; 257/100; 257/E33.068; 257/E33.058; 257/E33.059

(57) ABSTRACT

An LED includes a base having a depression, a chip disposed in the depression, an encapsulation received in the depression for encapsulating the chip, and a base. Two spaced electrodes are attached to a bottom of the base and electrically connect with the chips. A porous heat sink extends through the base and reaches the depression, contacting the chip.

### BACKGROUND

1. Technical Field

The present disclosure relates to a light emitting diode (LED), and more particularly to an LED incorporating a heat sink for improving heat dissipation thereof

2. Description of Related Art

Light emitting diodes (LEDs) are a commonly used light source in applications including illumination, signaling, signage and displays. The LED has several advantages over incandescent and fluorescent lamps, including high brightness, long life, and stable light output.

A conventional LED generally includes a base, a chip mounted on the base, and an encapsulation sealing the chip. When the LED is operated, about 80% of the electric power consumed by the LED is transformed into heat. The heat is then transferred to the base and dissipated to ambient air. However, the heat on the base cannot be quickly dissipated to ambient air from a relatively small heat exchange area of the base, and the LED may overheat, significantly reducing efficiency and service life thereof. Therefore, efficient dissipation of the heat of the LED becomes a challenge.

What is needed, therefore, is an LED having improved heat dissipation efficiency.

### BRIEF DESCRIPTION OF THE DRAWINGS

FIG. 1 is a cross-section of an LED in accordance with a first embodiment.

FIG. 2 is a cross-section of an LED in accordance with a second embodiment.

### DETAILED DESCRIPTION

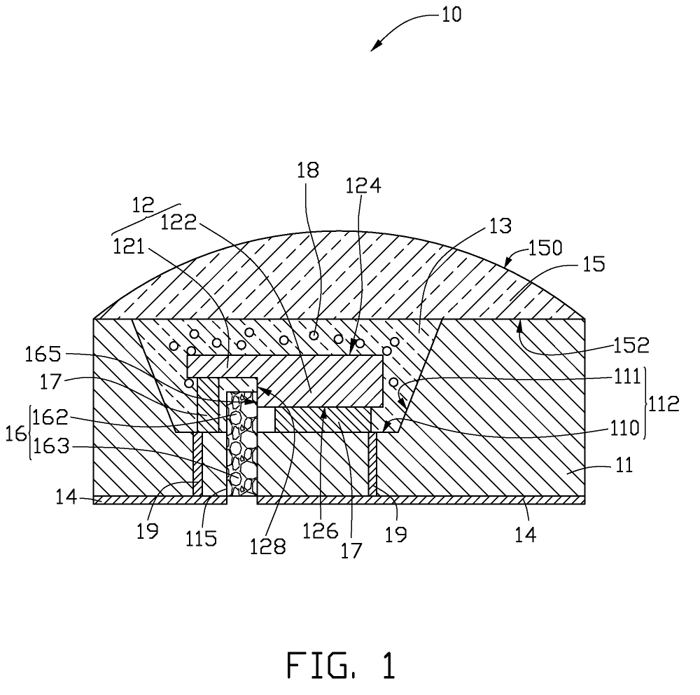

Referring to FIG. 1, an LED 10 in accordance with an exemplary embodiment is illustrated. The LED 10 includes a base 11, a chip 12, an encapsulation 13, two electrodes 14, a lens 15 and a heat sink 16.

Here, the base 11 is made of ceramics having good heat conduction. The base 11 has a concave configuration with a depression 112 defined in a top portion thereof. The depression 112 has a trapezoidal cross section. The base 11 has a flat supporting wall 110 formed at a bottom of the depression 112 and a sidewall 111 expanding upwardly from a periphery of the supporting wall 110. The supporting wall 110 and the sidewall 111 cooperatively define the depression 112 so that the depression 112 has a narrow bottom portion and a wide top portion.

The sidewall 111 is coated with a highly reflective material such as gold or sliver. The base 11 defines a mounting hole 115 vertically extending therethrough from the supporting wall 110 to a bottom surface of the base 11. The mounting hole 115 communicates the depression 112 with an exterior, i.e., a bottom of the base 11.

The chip 12 is disposed in the depression 112, and has a p-n junction structure. The chip 12 includes a thin portion 121 and a thick potion 122 along a horizontal axis. The thick portion 122 is thicker than the thin portion 121. The thin portion 121 and the thick portion 122 are the negative pole and positive pole of the chip 12. A top surface of the thin portion 121 is coplanar with a top surface of the thick portion 122, and a bottom surface of the thin portion 121 is higher than a bottom surface of the thick portion 122. Thus the chip 12 has a flat top surface 124 and a stepped bottom surface 126. The bottom surface 126 has two horizontal surfaces and a vertical surface 128 therebetween.

Two protrusions 17 extend upwardly from the supporting wall 110 to the bottom surface of the thin portion 121 and the bottom surface of the thick portion 122, respectively. The protrusions 17 are welding rods, being thermally and electrically conductive. The thin portion 121 and the thick portion 122 are respectively supported by the protrusions 17 and fixed to the supporting wall 110 by soldering to the protrusions 17. The mounting hole 115 is located under the thin portion 121 of the chip 12 and between the two protrusions 17.

The encapsulation 13 is received in the depression 112 of the base 11 for encapsulating the chip 12 as well as protecting the chip 12 from external trauma. The encapsulation 13 has a planar top surface coplanar with a top surface of the base 10. The encapsulation 13, a light penetrable material such as acryl, silicone, or epoxy resin, is uniformly mixed with fluorescent powder 18 to convert light emitted by the chip 12 into emitted light according to need.

The electrodes 14 are attached to the bottom surface of the base 11. The electrodes 14 are spaced from each other by the mounting hole 115. Two electric poles 19, respectively connecting to the electrodes 14, vertically extend through the base 14 to electrically connect with the protrusions 17 respectively. Thus, the electrodes 14 electrically connect with the thin portion 121 represented as P electrode and the thick portion 122 represented as N electrode of the chip 12 respectively, via the electric poles 19 and the protrusions 17. The electric poles 19 have better electrical conductivity than the base 11, which in nature is electrically insulated. The electric poles 19 can be metal, metal and resin compound, graphite, or graphite resin compound.

The heat sink 16, with an elongate shape, extends through the mounting hole 115 and reaches the depression 112 of the base 11. The heat sink 16 includes a top portion 162 received in the depression 112 and a lower portion 163 received in the mounting hole 115. The top portion 162 is under the thin portion 121 of the chip 12, and has a first surface 165 abutting the vertical surface 128 of the chip 12. The electrode 14, the electric pole 19, and the protrusion 17 connected to the thin portion 121 of the chip 12 are located at a first side of the heat sink 16, whereas the other electrode 14, the electric pole 19, and the protrusion 17 connected to the thick portion 122 of the chip 12 are located on a second side of the heat sink 16.

The heat sink 16 is thermally conductive and electrically insulated material, such as ceramics, which has a plurality of pores defined therein to increase heat exchange area thereof, whereby the heat sink 16 has heat exchange efficiency beyond that of the base 11.

The lens 15 is light penetrable material, such as plastic or glass. The lens 15 has a curved, convex top surface 150 and a flat bottom surface 152. The bottom surface 152 is attached to the top surfaces of the base 11 and the encapsulation 13. The top surface 150 of the lens 15 converges light emitted by the chip 12 so as to provide better illumination from the LED 10.

In operation, part of the heat generated by the chip 12 is transferred to the heat sink 16 through contacting surfaces of the vertical surface 128 of the chip 12 and the first surface 165 of the heat sink 16, and part of the heat of the chip 12 is transferred to the base 11 via the protrusions 17. Finally the heat is conducted downwardly and dissipated to ambient air. Because the heat sink 16 has better heat conductivity than the base 11, the heat of the LED 10 can be dissipated by the heat sink 10 more quickly than by a conventional LED.

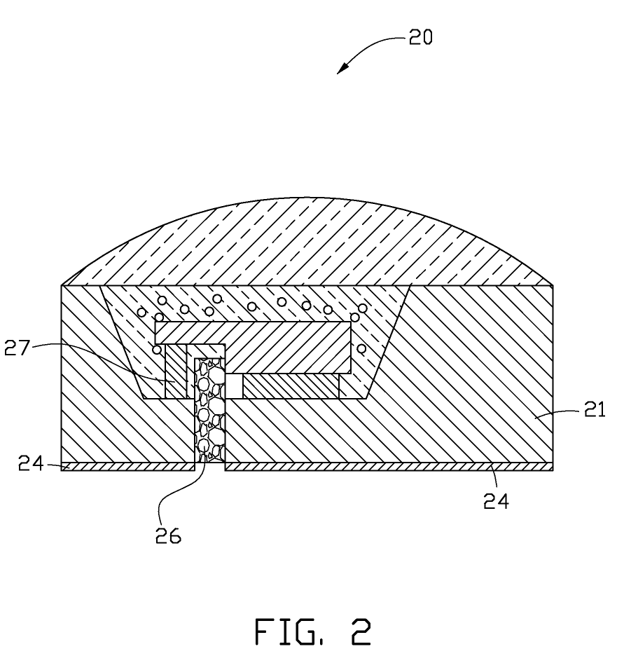

Referring to FIG. 2, an LED 20 according to a second embodiment is shown, differing from the previous embodiment only in that the electrodes 24 connect with the protrusions 27 merely via the base 21 so as to omit the need for electric poles. The heat sink 26 extends through and divides the base 21 into two spaced, electricity-insulated portions respectively located at left and right thereof by the heat sink 26. In this embodiment, the base 21 can be made of electrically and thermally conductive ceramics or metal having a good heat conductivity, such as aluminum.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED comprising:
a base comprising a depression defined in a top surface thereof;
a chip disposed in the depression;
an encapsulation received in the depression and encapsulating the chip;
two spaced electrodes attached to a bottom of the base and electrically connecting with the chips; and
a porous heat sink extending through the base and contacting the chip directly, dissipating heat generated during operation of the chip.

2. The LED of claim 1, wherein the heat sink extends upwardly through the base to reach the depression of the base.

3. The LED of claim 2, wherein the base includes a supporting wall at a bottom of the depression and a sidewall extending upwardly from a periphery of the supporting wall, wherein the supporting wall and the sidewall cooperatively define the depression, the supporting wall defines a mounting hole vertically extending through the base and communicates the depression with an exterior of the base, and the heat sink includes a top portion received in the depression and a lower portion received in the mounting hole.

4. The LED of claim 3, wherein two protrusions extend upwardly from the supporting wall to a bottom of the chip and support the chip thereon, with the top portion of the heat sink located therebetween.

5. The LED of claim 4, wherein the chip includes a thin portion and a thicker thick potion, wherein a bottom of the thin portion is higher than a bottom of the thick portion, and the top portion of the heat sink abuts a vertical surface between the bottom of the thin portion and the bottom of the thick portion of the chip.

6. The LED of claim 5, wherein the protrusions are welding rods, and have top ends thereof soldered to the thin portion and the thick portion, and bottom ends soldered to the supporting wall of the base.

7. The LED of claim 1, wherein the base is made of ceramics.

8. The LED of claim 7, wherein two electric poles, respectively connecting to the electrodes, vertically extend through the base to electrically connect with the chips respectively.

9. The LED of claim 8, wherein the electric poles each have electrical conductivity exceeding that of the base.

10. The LED of claim 8, wherein the electric poles are metal, graphite, metal/graphite compound, or graphite/resin compound.

11. The LED of claim 1, wherein the base is metal.

12. The LED of claim 11, wherein the heat sink is an electrically-insulated material, and wherein the heat sink extends horizontally through and divides the base into two spaced, electricity-insulated portions respectively located at the left and right sides by the heat sink.

13. The LED of claim 1, wherein the heat sink has an elongated shape.

14. The LED of claim 1 further comprising a lens mounted on the encapsulation and base, wherein the lens is light penetrable and includes a curved, convex top surface.

15. An LED comprising:
a base;
a chip mounted to the base;
an encapsulation encapsulating the chip; and
a porous heat sink received in the base and contacting the chip directly, with heat conductive efficiency of the heat sink exceeding that of the base.

16. The LED of claim 15, wherein the heat sink is elongated and extends through the base vertically.

17. The LED of claim 15, wherein the chip has a stepped bottom surface, one step thereof to which the heat sink attaches.
